(19) United States
(12) Patent Application Publication
(10) Pub. No.: US 2021/0210930 A1
(43) Pub. Date: Jul. 8, 2021

(54) TECHNIQUES FOR ELECTRICALLY ISOLATING N AND P-SIDE REGIONS OF A SEMICONDUCTOR LASER CHIP FOR P-SIDE DOWN BONDING

(71) Applicant: Applied Optoelectronics, Inc., Sugar Land, TX (US)

(72) Inventors: Kai-Sheng LIN, Sugar Land, TX (US); Yaohui GAO, Sugar Land, TX (US); Huanlin ZHANG, Sugar Land, TX (US)

(21) Appl. No.: 16/737,453

(22) Filed: Jan. 8, 2020

(51) Int. Cl. H01S 5/343; H01S 5/042; H01S 5/022

(52) U.S. Cl. CPC H01S 5/34326; H01S 5/02272; H01S 5/0421; H01S 5/3434

(57) ABSTRACT

In general, a MQW semiconductor laser chip with an electrically insulated P-side region and a process for forming the same is disclosed. The MQW semiconductor laser chip, also referred to herein as a MQW semiconductor laser or simply a semiconductor laser, includes a layer of electrically insulative material that extends along at least a portion of the sidewalls to minimize or otherwise reduce the potential for electrical shorts between P and N-sides of the same when utilizing P-side bonding techniques.

### TECHNICAL FIELD

The present disclosure relates to optical communications and more particularly, to techniques for forming a semiconductor laser chip with an electrically insulative layer to minimize or otherwise reduce the potential of an electrical short between N and P-regions when implementing P-down chip bonding.

### BACKGROUND INFORMATION

Optical transceivers are used to transmit and receive optical signals for various applications including, without limitation, internet data center, cable TV broadband, and fiber to the home (FTTH) applications. Optical transceivers provide higher speeds and bandwidth over longer distances, for example, as compared to transmission over copper cables. The desire to provide higher transmit/receive speeds in increasingly space-constrained optical transceiver modules has presented challenges, for example, with respect to thermal management, insertion loss, RF driving signal quality and manufacturing yield.

Optical transceiver modules generally include one or more transmitter optical subassemblies (TOSAs) for transmitting optical signals. TOSAs can include one or more lasers to emit one or more channel wavelengths and associated circuitry for driving the lasers. Some TOSAs utilize multi quantum well (MQW) semiconductor lasers for generating associated wavelengths. MQW semiconductor lasers can operate over a wide range of wavelengths including both visible and infrared wavelengths, e.g., based on material choices and layer dimensions. MQW semiconductor lasers generally include a layer stack that includes a P-side and an N-side for electrical connectivity with driver circuitry. P-side bonding of an MQW semiconductor to a substrate, e.g., a printed circuit board, allows for better thermal performance but raises numerous non-trivial challenges.

### BRIEF DESCRIPTION OF THE DRAWINGS

These and other features and advantages will be better understood by reading the following detailed description, taken together with the drawings wherein:

FIG. 1 shows an example MQW semiconductor laser mounted to a substrate utilizing P-side up bonding.

FIG. 2 shows an example MQW semiconductor laser mounted to a substrate utilizing P-side down bonding.

FIG. 3 shows a cross-sectional view of the example MWQ buried heterostructure (BH) semiconductor laser of FIG. 2.

FIG. 4 shows a cross-sectional view of a MQW semiconductor laser in accordance with an embodiment of the present disclosure.

FIG. 5 shows an example process for forming a MQW semiconductor laser in accordance with embodiments of the present disclosure.

FIG. 6 shows an example substrate suitable for use during the formation of a MQW semiconductor laser utilizing the process of FIG. 5.

FIG. 7 shows the example substrate of FIG. 6 after etching to form a MQW semiconductor laser utilizing the process of FIG. 5.

FIG. 8 shows the example substrate of FIG. 6 after depositing/forming an insulation layer to form a MQW semiconductor laser utilizing the process of FIG. 5.

FIG. 9 shows an example MQW semiconductor formed utilizing the process of FIG. 5.

FIG. 10 shows an example approach to v-groove etching during the process of FIG. 5, in accordance with an embodiment.

FIG. 11 shows an example transceiver system capable of implementing a MQW semiconductor laser consistent with the present disclosure.

### DETAILED DESCRIPTION

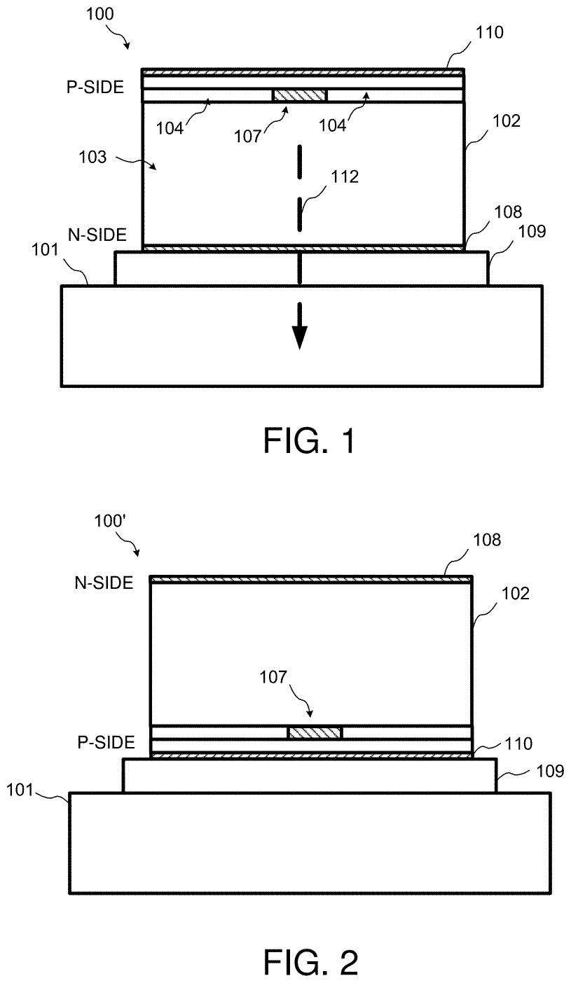

As discussed above, MQW semiconductor lasers can include a layer stack/architecture whereby the N-side, MQW and P-side regions of a chip are grown sequentially. For example, FIG. 1 shows a simplified cross-section of a MQW semiconductor laser 100 with an N-side bonded to substrate 101 by way of solder 109. The MQW semiconductor laser 100 includes a body formed of a substrate 102. The MQW semiconductor laser 100 can be formed using standard semiconductor processes, e.g., photolithography, to provide one or more layers of an N-type material 103 to provide an N-type region with a metal contact 108 (referred to also as P-side metal), and a plurality of layers to form an MQW section 107 and associated metal contact 110 (referred to herein also as N-side metal). As further shown, layers of electrically insulating material 104 can confine the current spreading. One disadvantage of N-side bonding, such as shown in FIG. 1, is that thermal dissipation is relatively poor as the thermal path through the MQW semiconductor laser 100 passes through a majority of the chip generally along thermal path 112.

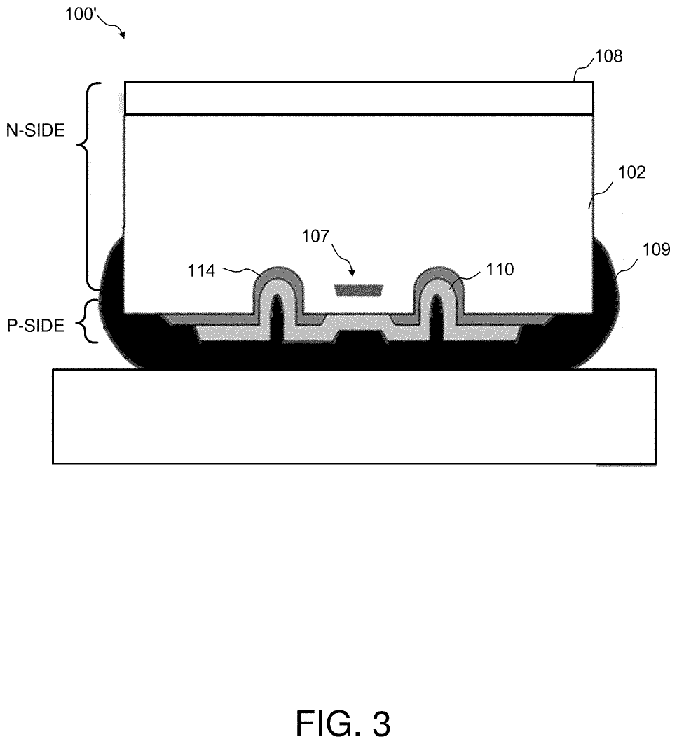

In contrast, FIG. 2 shows a simplified cross-section of a MQW semiconductor laser 100′ with a P-side bonded to the substrate 101. As shown, the MQW semiconductor laser 100′ is substantially similar to that of the MQW semiconductor laser 100 of FIG. 1, but in an orientation that includes the P-side being bonded to the substrate 101. However, the p-side of the MQW semiconductor laser 100 has a thickness that is about 2-10% of that of the n-side. For instance, as shown more clearly in FIG. 3, the N-side can measure about 90 microns and the P-side can measure about 2 microns. The solder 109 can be between about 5-10 microns, for instance, which makes such a P-side down orientation prone to electrical shorts. For instance, as shown in FIG. 3, the solder 109 can reflow and engage/contact the scribe line area and sidewall of the MQW semiconductor laser 100′. This contact can result in a short between the P-side and N-side metal, and ultimately, chip failure. An insulating layer, such as oxide passivation layer 114 can mitigate some risks of shorts, but scribe line and sidewall of the MQW semiconductor laser 100′ remain prone to shorts.

In general, a MQW semiconductor laser chip with an electrically insulated P-side region and a process for forming the same is disclosed. The MQW semiconductor laser chip, also referred to herein as a MQW semiconductor laser or simply a semiconductor laser, includes a layer of electrically insulative material that extends along at least a portion of the sidewalls to minimize or otherwise reduce the potential for electrical shorts between P and N-sides of the same when utilizing P-side bonding techniques.

In an embodiment, the semiconductor laser chip includes a substrate formed of a first semiconductor material, and a cladding layer formed of an N-type material disposed on the substrate. The semiconductor laser chip further includes a first layer of metallic material disposed on a first end of the substrate to provide an N-side metal contact in electrical communication with the cladding layer of the N-type material, and a multi quantum well (MQW) disposed adjacent a second end of the substrate. A first layer of electrically insulative material is disposed on the second end of the substrate, and a second layer of metallic material is disposed on the second end of the substrate to provide a P-side metal contact in electrical communication with the MQW. The layer of electrically insulative material is disposed on at least a portion of the second end of the substrate and on a first sidewall of the substrate, the sidewall adjoining the first and second ends of the substrate.

A process for forming a semiconductor laser chip consistent with the present disclosure can include introducing a V-groove via etching on to a wafer of semiconductor material. The v-groove forms a well/trench that allows for deposition/formation of the electrically insulative material. The v-groove further provides a etch/scribe line to simplify cutting/separation of the wafer material into substrates for further semiconductor processing to form a MQW semiconductor laser. Once separated, the V-groove region provides a notch on sidewalls of each substrate that advantageously confines solder/reflowed material, and further electrically insulates sidewalls adjacent a P-side region of the MQW semiconductor. The notches and associated electrically insulative material of each formed MQW semiconductor eliminates or otherwise significantly reduces electrical shorts when implementing P-side bonding.

As used herein, “channel wavelengths” refer to the wavelengths associated with optical channels and may include a specified wavelength band around a center wavelength. In one example, the channel wavelengths may be defined by an International Telecommunication (ITU) standard such as the ITU-T dense wavelength division multiplexing (DWDM) grid. This disclosure is equally applicable to coarse wavelength division multiplexing (CWDM). In one specific example embodiment, the channel wavelengths are implemented in accordance with local area network (LAN) wavelength division multiplexing (WDM), which may also be referred to as LWDM.

The term “coupled” as used herein refers to any connection, coupling, link or the like and “optically coupled” refers to coupling such that light from one element is imparted to another element. Such “coupled” devices are not necessarily directly connected to one another and may be separated by intermediate components or devices that may manipulate or modify such signals. On the other hand, the term “direct optical coupling” refers to an optical coupling via an optical path between two elements that does not include such intermediate components or devices, e.g., a mirror, waveguide, and so on, or bends/turns along the optical path between two elements.

The term substantially, as generally referred to herein, refers to a degree of precision within acceptable tolerance that accounts for and reflects minor real-world variation due to material composition, material defects, and/or limitations/peculiarities in manufacturing processes. Such variation may therefore be said to achieve largely, but not necessarily wholly, the stated/nominal characteristic. To provide one non-limiting numerical example to quantify “substantially,” such a modifier is intended to include minor variation that can cause a deviation of up to and including ±5% from a particular stated quality/characteristic unless otherwise provided by the present disclosure.

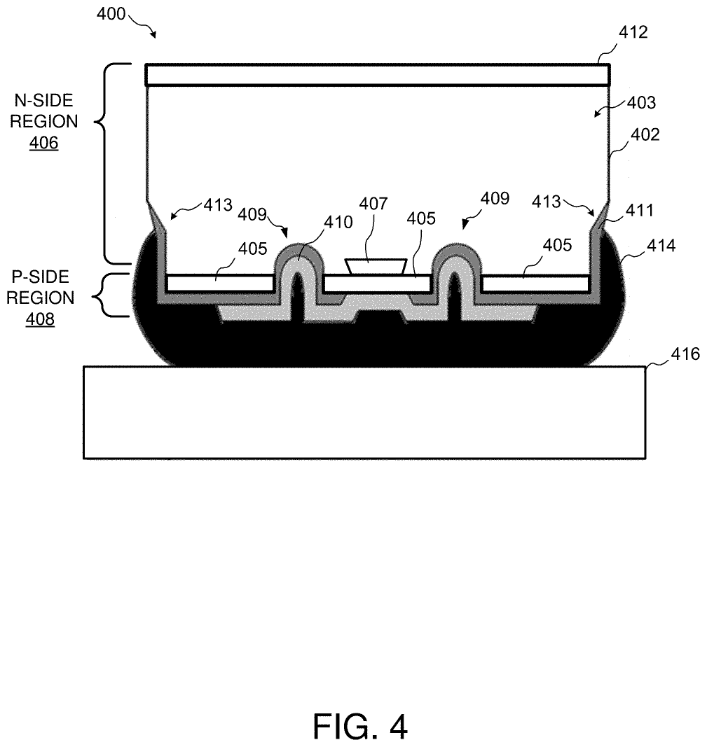

FIG. 4 shows a cross-sectional view of a laser device 400 that implements a multi quantum well (MQW) laser structure consistent with the present disclosure. As shown, the laser device 400 includes a semiconductor substrate 402 (referred to herein as simply a substrate) implemented with a double heterostructure provided by the n and p-side regions 406, 408 as discussed below.

The substrate 402 comprises a suitable substrate material such as, for instance, bulk, gallium arsenide (GaAs), indium phosphide (InP), or any other suitable III-V semiconductor material.

The substrate 402 includes at least one layer of N-type cladding material 403 grown thereon to provide at a portion of N-side region 406. The N-type cladding material 403 may also be referred to herein simply as N-type cladding. A first layer of metallic material 412 is disposed on a surface of the substrate 402 to provide a metal contact/terminal. The first layer of metallic material 412 may also be referred to herein as simply N-side metal.

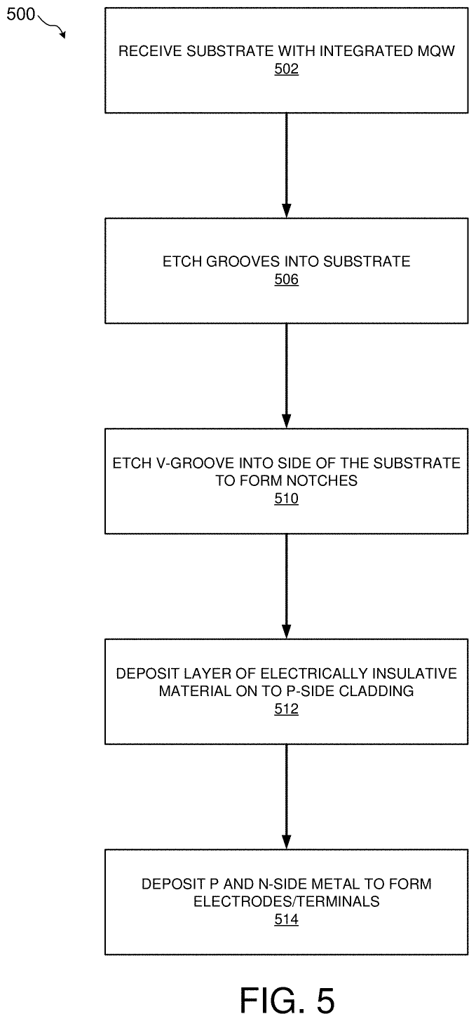

Opposite the layer of metallic material 412, the substrate 402 further includes a plurality of mesa-like structures defined at least in part by grooves 409. The grooves 409 may be introduced via, for instance, etching or other suitable process as is discussed in further detail below with regard to the example process of FIG. 5. In the embodiment of FIG. 4, the substrate includes two grooves 409 which extend parallel with each other and longitudinally along the substrate 402. The two grooves 409 are equally spaced relative to each other and include a generally arcuate/round u-shaped profile, although other shapes and channel spacing configurations are within the scope of this disclosure.

Continuing on, each of the mesa-like structures include a layer of P-type cladding material 405 disposed thereon, which may be referred to herein as simply the P-side cladding. The P-side cladding 405 provide at least a portion of the P-side region 408. A multi quantum well (MQW) 407 is disposed/formed between the N-side and P-side regions 406, 408 to provide an active region. In an embodiment, the structure of the MQW can include InGaAsP with different composition to form quantum well and barrier. The MQW 407 mesa is formed by chemical etching away original semiconductor material and regrowing electric-insulating material, such as InP. The particular shape/profile of the MQW 407 can vary and the example illustrated in FIG. 4 is not intended to be limiting.

As further shown in the FIG. 4, the substrate 402 includes notches/channels 413 disposed along an outer edge that provide the substrate 402 with a taper at one end that is adjacent the mesa structures and MQW 407. The notches 413 extend longitudinally along the substrate 402 along an outer edge of the same, and substantially parallel with the MQW 407. The notches 413 may be formed via a v-groove etched into the substrate 402, as will be discussed in greater detail below. A layer of electrically insulating material 411 is deposited on the P-side region 408, and in particular, on the P-type cladding material 405 and at least a portion of the notches 413. Preferably, the layer of electrically insulative material 411 comprises an oxide such as SiO2 or SiN for purposes of providing a passivation layer.

A layer of metallic material 410 is disposed on at least a portion of the electrically insulative material 411 and a portion of the P-type cladding material 405 which is adjacent the MQW 407 to provide a P-side metal contact/terminal. The layer of metallic material 410 may therefore be electrically coupled to the MQW by way of the P-type cladding material 405, and electrically isolated from the N-side cladding material 403 by virtue of the electrically insulative material 411.

As shown, the notches 413 and associated layer of electrically insulative material 411 provide a confinement region for solder 414 to bond the laser device 400 to the printed circuit board 416, although the laser device 400 can mount to other substrates depending on a desired configuration. The solder 414 can be reflowed and electrically couple to the P-side metal contact/terminal provided by the layer of metallic material 410, with the notches 413 providing a block/dam to prevent an electrical short with the N-type cladding material 403.

### Methodology and Architecture

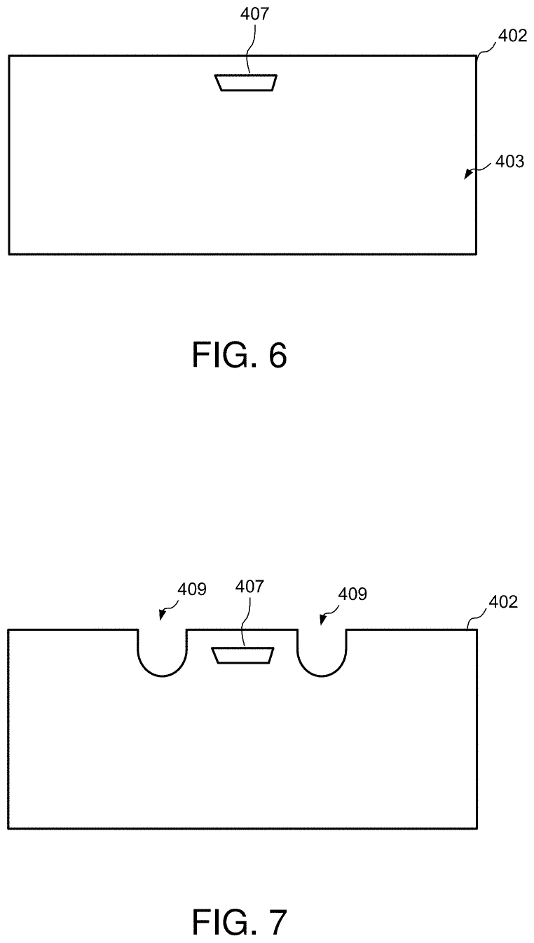

Turning to FIG. 5, with additional reference to FIGS. 5-11, one example process 500 suitable for forming a MQW semiconductor laser consistent with the present disclosure is shown. Specific acts of the example process 500 may be performed using semiconductor photolithography approaches including, for example, chemical vapor deposition (VPD), epitaxial growth, and other processes as discussed below. The example process 500 may not necessarily be performed in the order shown in FIG. 5, and various acts may be omitted, augmented, or added with minor modification.

In act 502, the process 500 includes receiving a substrate 402 including N-side material 403, MQW, P-side material/cladding 405 which are grown by epitaxial growth using molecular-beam epitaxy (MBE), metalorganic vapor-phase epitaxy (MOVPE), or other suitable technique.

In act 506, the process 500 includes etching the grooves 409 on both sides of the MQW 407 (See FIG. 7). Etching the grooves 409 can include, for instance, photolithography and wet etching, although other approaches are within the scope of this disclosure.

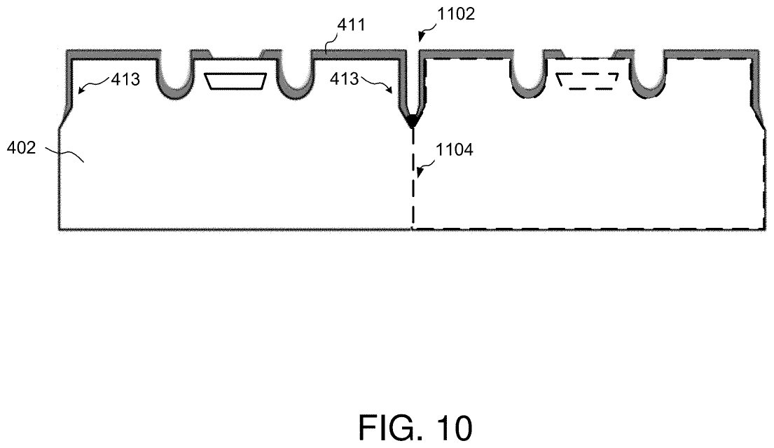

In act 510, the process 500 includes etching a v-groove into the substrate 402 to form notches 413. As shown in FIG. 10, a v-groove 1102 can be introduced to both introduce/form notches 413 but also to delineate/partition different portions of a wafer during semiconductor processing. The v-groove 1102 may therefore be used as an etch/scribe line 1104 to simplify cutting and separation of adjacent substrate portions. The v-groove 1102 also provides a trench for depositing/forming electrically insulative material in act 512.

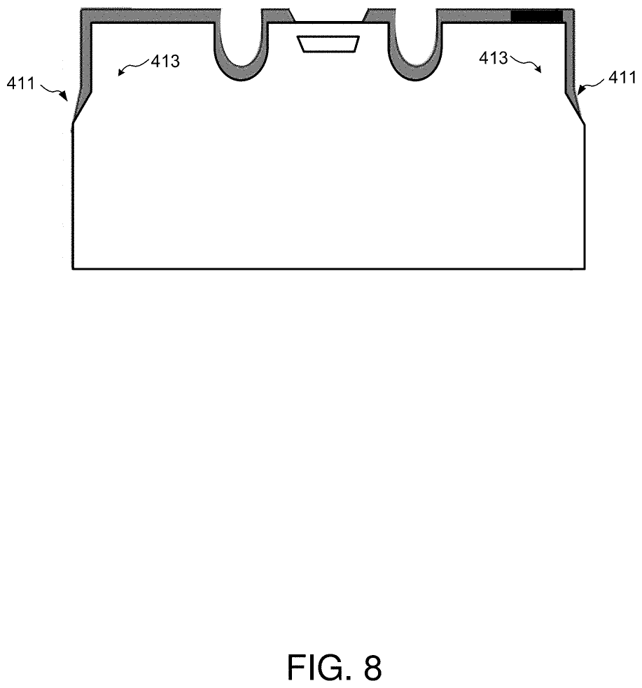

In act 512, a layer of electrically insulative material 411 gets disposed on to the P-type cladding material 405 and the notches 413. Deposition of the insulative material 411 can include blanket deposition, or selective deposition (See FIG. 8). As shown in FIG. 10, deposition of the layer of electrically insulative material 411 can include depositing the material in the v-groove formed between adjacent substrates prior to cutting/separation of the same. In the example embodiment of FIG. 10, this allows the v-grooves to act as trench to confine the layer of electrically insulative material 411.

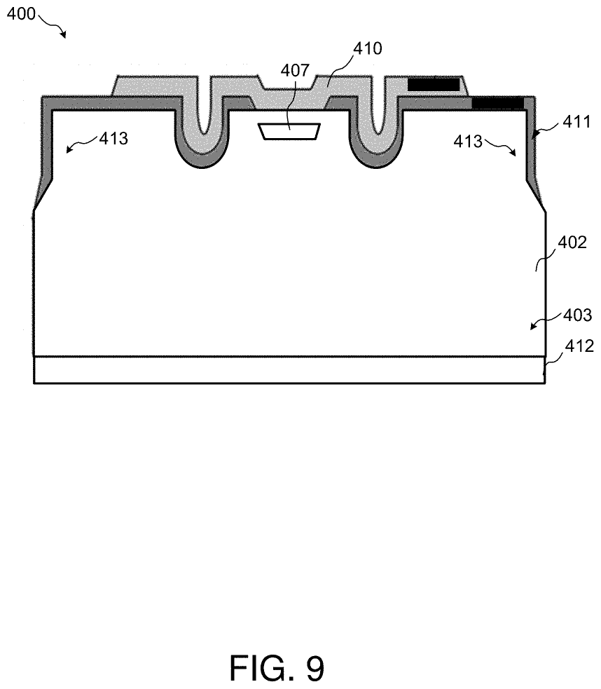

In act 514, the process 500 includes depositing/forming P and N-side metal to form electrodes/terminals. Formation of the P-side metal can include depositing/forming a layer of metallic material 410 on the P-type material 405. Likewise, formation of the N-side metal can include depositing/forming a layer of metallic material 412 on to the substrate 402, and more particularly, on to the N-type cladding 403 to introduce electrical connectivity therebetween. FIG. 9 shows an example of the laser device 400 after formation via example process 500.

### Example Optical Transceiver System

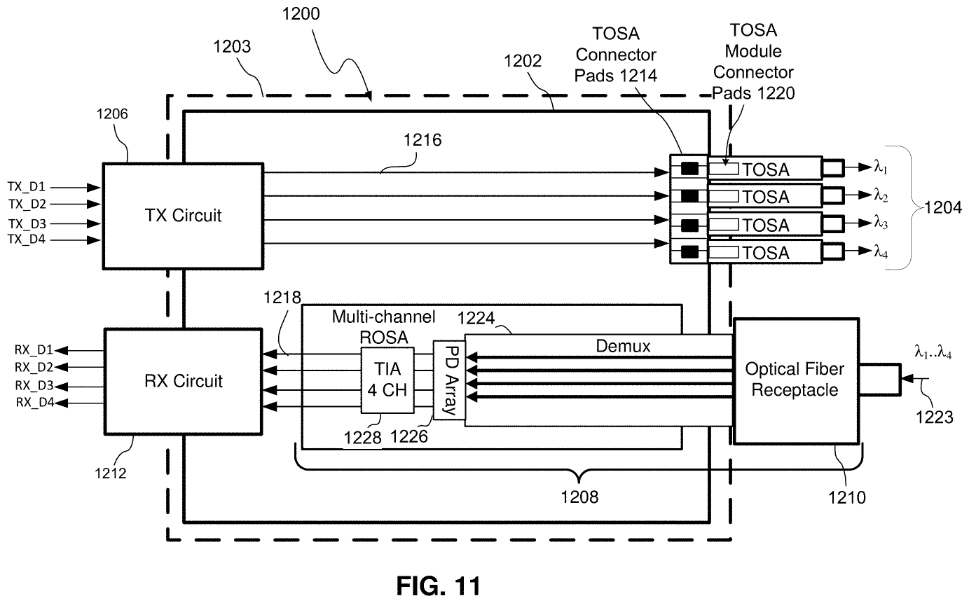

FIG. 11 illustrates an optical transceiver module 1200, consistent with embodiments of the present disclosure. The optical transceiver module 1200 is shown in a highly simplified form for clarity and ease of explanation and not for purposes of limitation. In this embodiment, the optical transceiver module 1200 can be pluggable (e.g., comports with pluggable small form factor (SFFP) standards) and transmits and receives four (4) channels using four different channel wavelengths (λ1, λ2, λ3, λ4) and may be capable of transmission rates of at least about 25 Gbps per channel. In one example, the channel wavelengths λ1, λ2, λ3, λ4 may be within a ±13 nm range and have respective channel wavelengths of 1270 nm, 1290 nm, 1310 nm, and 1330 nm, respectively. Other channel wavelengths and configurations are within the scope of this disclosure including those associated with local area network (LAN) wavelength division multiplexing (WDM). For instance, the optical transceiver module 1200 can include up to eight (8) or more channels and provide transmission rates of at least 25 Gbps per channel. Note, the present disclosure is equally applicable to other types of optical subassembly modules and optical devices such as single and multi-channel optical transmitters, and single and multi-channel optical receivers.

The optical transceiver module 1200 may also be capable of transmission distances of 2 km to at least about 10 km. The optical transceiver module 1200 may be used, for example, in internet data center applications or fiber to the home (FTTH) applications.

In an embodiment, the optical transceiver module 1200 is disposed in a transceiver housing 1203. The transceiver housing 1203 can be configured with one or more cavities to receive one or more optical transceiver modules, depending on a desired configuration.

The optical transceiver module 1200 includes a number of components to support transceiver operations. As shown, the optical transceiver module 1200 includes an optical transceiver substrate 1202, a plurality of transmitter optical subassemblies (TOSA) modules 1204 for transmitting optical signals having different channel wavelengths, a transmit connecting circuit 1206, a multi-channel receiver optical subassembly (ROSA) arrangement 1208 for receiving optical signals on different channel wavelengths, an optical fiber receptacle 1210 to receive and align a fiber connector (e.g., a ferrule) with the ROSA, and a receiver connecting circuit 1212. Note, an external multiplexing device (not shown), e.g., an arrayed waveguide grating (AWG), can receive channel wavelengths emitted by the TOSA modules (λ1 . . . λ4) and multiplex the same into a transmit signal, e.g., a wavelength-division multiplex (WDM) signal. However, the optical transceiver module 1200 can include a local multiplexing device, e.g., an AWG mounted on the optical transceiver substrate 1202, for outputting an optical signal with multiple channel wavelengths. The particular configuration of the optical transceiver module 1200 shown in FIG. 11 is not intended to be limiting.

Continuing on, the optical transceiver substrate 1202 includes traces, connector pads, and other circuitry to support transceiver operations. The optical transceiver substrate 1202 may include TOSA connector pads 1214 (or terminals 1214) that enable each of the TOSA modules 1204 to mount and electrically couple to the optical transceiver substrate 1202. The TOSA connector pads 1214 may also be referred to herein as a simply connector pads. The optical transceiver substrate 1202 may include traces 1216 that couple the TOSA connector pads 1214 to the transmit connecting circuit 1206.

The ROSA arrangement includes an optical fiber receptacle 1210, demultiplexing device 1224, photodiode (PD) array 1226, and a transimpedance amplifier (TIA) 1228. The optical transceiver substrate 1202 can include traces 1218 that electrically couple the ROSA arrangement 1208 to the receiver connecting circuit 1212. The ROSA arrangement can receive a multiplexed input signal 1223 via the optical fiber receptacle 1210. The demultiplexer includes an input aligned with the optical fiber receptacle to receive the multiplex input signal. The demultiplexing device 1224 separates the multiplexed input signal into constituent wavelengths and outputs each separated channel wavelength via a corresponding output onto PD array 1226. The PD array 1226 outputs electrical signals proportional to detected wavelengths. The TIA 1228 receives the outputted electrical signals from the PD array 1226 and filters and/or amplifies the same. The TIA 1228 outputs the amplified signals to the receive connecting circuit 1212 by way of traces 1218.

The optical transceiver substrate 1202 may provide an optical transceiver module that may be “plugged” into an optical transceiver cage. Therefore, the transmit connecting circuit 1206 and the receiver connecting circuit 1212 may electrically couple to external circuitry of the optical transceiver cage. The optical transceiver substrate 1202 may be manufactured from a multi-layer printed circuitry board (PCB), although other types of substrates may be utilized and are within the scope of this disclosure.

Each of the TOSA modules 1204 may be configured to receive driving electrical signals (TX_D1 to TX_D4) and emit associated channel wavelengths. The emitted channel wavelengths (λ1 . . . λn) can then be output to a multiplexer (not shown) to multiplex the same into a signal transmit signal. Each of the TOSA modules 1204 may be electrically coupled to the TOSA connector pads 1214 and to the traces 1216 through TOSA module connector pads 1220. Each of the TOSA modules 1204 include a laser arrangement that includes at least one laser diode device and supporting circuitry. Preferably, each TOSA module 1204 implements one or more MQW semiconductor laser as variously disclosed herein.

In accordance with an aspect of the present disclosure a semiconductor laser chip is disclosed. The semiconductor laser chip comprising a substrate formed of a first semiconductor material, a cladding layer formed of an N-type material disposed on the substrate, a first layer of metallic material disposed on a first end of the substrate to provide an N-side metal contact in electrical communication with the cladding layer of the N-type material, a multi quantum well (MQW) disposed adjacent a second end of the substrate, a first layer of electrically insulative material disposed on the second end of the substrate, a second layer of metallic material disposed on the second end of the substrate to provide a P-side metal contact in electrical communication with the MQW, and wherein the layer of electrically insulative material is disposed on at least a portion of the second end of the substrate and on a first sidewall of the substrate, the sidewall adjoining the first and second ends of the substrate.

In accordance with another aspect of the present disclosure an optical subassembly module for transmitting at least one channel wavelength is disclosed. The optical subassembly module comprising a printed circuit board, a laser arrangement including at least one multi quantum well (MQW) semiconductor laser coupled to the printed circuit board, the at least one MQW semiconductor laser having a P-side region at a first end and an N-side region at a second end, and a plurality of sidewalls adjoining the first and second ends, and wherein at least one layer of electrically insulative material is disposed on the P-side region of the second end and at least partially along the plurality of sidewalls, and solder material disposed between the at least one MQW semiconductor laser and the printed circuit board, and wherein the at least one layer of electrically insulative material disposed at least partially along the plurality of sidewalls of the MQW semiconductor electrically insulates the N-side region from electrically shorting with the solder material.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure, which is not to be limited except by the following claims.

What is claimed is:

1. A semiconductor laser chip, the semiconductor laser chip comprising:
a substrate formed of a first semiconductor material;
a cladding layer formed of an N-type material disposed on the substrate;
a first layer of metallic material disposed on a first end of the substrate to provide an N-side metal contact in electrical communication with the cladding layer of the N-type material;
a multi quantum well (MQW) disposed adjacent a second end of the substrate;
a first layer of electrically insulative material disposed on the second end of the substrate;
a second layer of metallic material disposed on the second end of the substrate to provide a P-side metal contact in electrical communication with the MQW; and
wherein the layer of electrically insulative material is disposed on at least a portion of the second end of the substrate and on a first sidewall of the substrate, the sidewall adjoining the first and second ends of the substrate.

2. The semiconductor laser chip of claim 1, wherein the first sidewall defines a first notch that extends from the second end towards the first end, and wherein the first layer of electrically insulative material is disposed on the notch.

3. The semiconductor laser chip of claim 2, wherein the substrate further includes a second sidewall that adjoins the first and second ends, and wherein the second sidewall defines a second notch.

4. The semiconductor laser chip of claim 3, further comprising a second layer of electrically insulative material disposed on the second end of the substrate and the second notch.

5. The semiconductor laser chip of claim 1, wherein the substrate comprises a III-V semiconductor material.

6. The semiconductor laser chip of claim 1, wherein the N-type material comprises gallium arsenide (GaAs) or indium phosphide (InP).

7. The semiconductor laser chip of claim 1, wherein the MQW comprises a buried heterostructure.

8. The semiconductor laser chip of claim 1, wherein the electrically insulative layer is an oxidation passivation layer comprising silicon dioxide (SiO2) or silicon nitride.

9. The semiconductor laser chip of claim 1, wherein the second end of the substrate defines first and second channels, and wherein the MQW is disposed between the first and second channels.

10. The semiconductor laser chip of claim 1, implemented as an infrared laser capable of emitting channel wavelengths of 1300 nm to 1700 nm.

11. An optical subassembly module for transmitting at least one channel wavelength, the optical subassembly module comprising:
a printed circuit board;
a laser arrangement including at least one multi quantum well (MQW) semiconductor laser coupled to the printed circuit board, the at least one MQW semiconductor laser having a P-side region at a first end and an N-side region at a second end, and a plurality of sidewalls adjoining the first and second ends, and wherein at least one layer of electrically insulative material is disposed on the P-side region of the second end and at least partially along the plurality of sidewalls; and
solder material disposed between the at least one MQW semiconductor laser and the printed circuit board, and wherein the at least one layer of electrically insulative material disposed at least partially along the plurality of sidewalls of the MQW semiconductor electrically insulates the N-side region from electrically shorting with the solder material.

12. The optical subassembly module of claim 11, wherein the at least one MQW semiconductor laser comprises at least one notch along the plurality of sidewalls, and wherein the at least one layer of electrically insulative material is disposed on the notch.

13. The optical subassembly module of claim 12, wherein the notch is formed at least partially as a V-groove.

14. The optical subassembly module of claim 11, wherein the P-side region has an overall thickness that is less than the N-side region.

15. The optical subassembly module of claim 11 implemented as a multi-channel optical transceiver capable of transmitting and receiving at least four different channel wavelengths.
